(19) United States
(12) Patent Application Publication
(10) Pub. No.: US 2019/0100635 A1
(43) Pub. Date: Apr. 4, 2019

(54) METHOD FOR PRODUCING LIQUID COMPOSITION CONTAINING FLUORORESIN POWDER

(71) Applicant: AGC INC., Chiyoda-ku (JP)

(72) Inventors: Tomoya HOSODA, Chiyoda-ku (JP); Tatsuya TERADA, Chiyoda-ku (JP)

(73) Assignee: AGC INC., Chiyoda-ku (JP)

(21) Appl. No.: 16/207,769

(22) Filed: Dec. 3, 2018

Related U.S. Application Data
(63) Continuation of application No. PCT/JP2017/023092, filed on Jun. 22, 2017.

(30) Foreign Application Priority Data
Jun. 23, 2016 (JP) 2016-124649

(51) Int. Cl. C08J 5/24; B32B 27/30; B32B 15/08; H05K 1/03; C08L 101/04

(52) U.S. Cl. CPC C08J 5/24; B32B 27/304; B32B 15/08; H05K 1/036; H05K 2201/015; C08J 2327/12; B32B 2307/206; B32B 2457/08; C08L 101/04

(57) ABSTRACT

To provide a method for producing a liquid composition, whereby agglomeration of the resin powder is suppressed even at a low viscosity and it is possible to obtain a uniformly dispersed liquid composition, and a method for producing a film, etc. by using the method for producing a liquid composition. The method for producing a liquid composition comprises heat-treating a mixture comprising a resin powder having an average particle size of from 0.02 to 200 μm made from a powder material containing a fluorinated polymer having a specific functional group, a binder component having a reactive group reactive with the functional group of the resin powder, and a liquid medium capable of dissolving the binder component, to obtain a liquid composition, of which the viscosity change rate to the viscosity before heating is from 5 to 200%. Further, the method for producing a film, etc. uses the liquid composition obtained by the method for producing a liquid composition.

### TECHNICAL FIELD

The present invention relates to a method for producing a liquid composition containing a fluororesin powder, and methods for producing a film, a fiber reinforced film, a prepreg, an adhesive substrate, a metal laminate and a printed circuit board by using the liquid composition.

### BACKGROUND ART

In recent years, along with weight reduction, size reduction and high densification of electronic products, demand for various printed circuit boards has been expanded. As a printed circuit board, for example, one prepared by laminating a metal foil on a substrate made of an insulating material such as a polyimide and forming a circuit by patterning the metal foil, is used. The printed circuit board is required to have excellent electrical characteristics (a low dielectric constant, etc.) corresponding to the frequency of a high frequency band, excellent heat resistance to withstand solder reflow, etc.

As a material having a low dielectric constant and being useful for a printed circuit board, a film has been proposed which comprises a resin composition having a fluoropolymer fine powder with an average particle size of from 0.02 to 5 μm filled in a polyimide (Patent Document 1). Such a film is produced by a method wherein a liquid composition prepared by mixing a fluoropolymer fine powder to a polyamic acid solution is applied on a flat surface and dried, followed by heat treatment in a high temperature oven to imidize the polyamic acid. However, in the method, the fluoropolymer fine powder is likely to be agglomerated and its dispersion tends to be non-uniform in the liquid composition, and consequently, also in the film to be formed, its dispersion tends to be non-uniform, whereby the electrical characteristics may sometimes be lowered.

Further, as a material useful for a printed circuit board, a laminate has been proposed which is obtained by forming, on a metal foil, a layer comprising a resin powder with an average particle size of from 0.02 to 50 μm containing a fluoropolymer having a functional group such as carbonyl group-containing group, and a cured product of a thermosetting resin (Patent Document 2). Such a laminate is produced by a method wherein a liquid composition having the resin powder dispersed in a solution containing the thermosetting resin is applied to the surface of e.g. a metal foil, dried and cured. However, also in this method, the resin powder is likely to be agglomerated and its dispersion tends to be non-uniform in the liquid composition, and consequently, also in the layer to be formed, its dispersion tends to be non-uniform, whereby the electrical characteristics may sometimes be lowered.

Agglomeration of the fluoropolymer fine powder or the resin powder in such a liquid composition is remarkable when the viscosity of the liquid composition is low.

### PRIOR ART DOCUMENTS

### Patent Documents

Patent Document 1: JP-A-2005-142572

Patent Document 2: WO2016/017801

### DISCLOSURE OF INVENTION

### Technical Problem

It is an object of the present invention to provide a method for producing a liquid composition, whereby agglomeration of a resin powder is suppressed even at a low viscosity and it is possible to obtain a uniformly dispersed liquid composition, and methods for producing a film, a fiber-reinforced film, a prepreg, an adhesive substrate, a metal laminate and a printed circuit board, by using the method for producing a liquid composition.

### Solution to Problem

The present invention has the following constructions.
[1] A method for producing a liquid composition, comprising heat-treating a mixture comprising a resin powder having an average particle size of from 0.02 to 200 μm made of a powder material containing the following polymer (X), a binder component having a reactive group reactive with the functional group of the resin powder, and a liquid medium capable of dissolving the binder component, to obtain a liquid composition, of which the viscosity change rate to the viscosity before heating is from 5 to 200%,

Polymer (X): a fluorinated polymer having units based on tetrafluoroethylene, and having at least one functional group selected from the group consisting of a carbonyl group-containing group, a hydroxy group, an epoxy group and an isocyanate group.
[2] The method for producing a liquid composition according to [1], wherein the polymer (X) is a copolymer containing units having the functional group and units based on tetrafluoroethylene.
[3] The method for producing a liquid composition according to [1] or [2], wherein the melting point of the polymer (X) is from 260 to 380° C.
[4] The method for producing a liquid composition according to any one of [1] to [3], wherein the polymer (X) is a melt-moldable fluorinated copolymer having a melting point of from 260 to 320° C.
[5] The method for producing a liquid composition according to any one of [1] to [4], wherein the polymer (X) is a copolymer containing units having the functional group, units based on tetrafluoroethylene and units based on a perfluoro(alkyl vinyl ether), in which the proportions of the respective units to the total of all units are as follows:

Units having the functional group: from 0.01 to 3 mol %,

Units based on tetrafluoroethylene: from 90 to 99.89 mol %,

Units based on a perfluoro(alkyl vinyl ether): from 0.1 to 9.99 mol %.
[6] The method for producing a liquid composition according to any one of [1] to [5], wherein the functional group is a carbonyl group-containing group, and said carbonyl group-containing group is a group having a carbonyl group between carbon atoms of a hydrocarbon group, a carbonate group, a carboxy group, a haloformyl group, an alkoxycarbonyl group or an acid anhydride residual group.
[7] The method for producing a liquid composition according to any one of [1] to [6], wherein the average particle size of the resin powder is from 0.02 to 10 μm.
[8] The method for producing a liquid composition according to any one of [1] to [7], wherein the reactive group is a carbonyl group-containing group, a hydroxy group, an amino group or an epoxy group.
[9] The method for producing a liquid composition according to any one of [1] to [8], wherein said mixture further contains a filler.
[10] A method for producing a film, comprising obtaining a liquid composition by the method for producing a liquid composition as defined in any one of [1] to [9], and conducting film formation by using the obtained liquid composition, followed by drying and then by heating to obtain a film.
[11] A method for producing a fiber-reinforced film, comprising obtaining a liquid composition by the method for producing a liquid composition as defined in any one of [1] to [9], and impregnating a reinforcing fiber base material with the obtained liquid composition, followed by drying and then by heating to obtain a fiber-reinforced film.
[12] A method for producing a prepreg, comprising obtaining a liquid composition by the method for producing a liquid composition as defined in any one of [1] to [9], and impregnating a reinforcing fiber base material with the obtained liquid composition, followed by drying to obtain a prepreg.
[13] A method for producing an adhesive substrate, comprising obtaining a liquid composition by the method for producing a liquid composition as defined in any one of [1] to [9], and applying the obtained liquid composition on at least one surface of a substrate, followed by drying and then by heating to obtain an adhesive substrate.
[14] A method for producing a metal laminate, comprising obtaining a film by the method for producing a film as defined in [10], or obtaining a fiber-reinforced film by the method for producing a fiber-reinforced film as defined in [11], or obtaining a prepreg by the method for producing a prepreg as defined in [12], or obtaining an adhesive substrate by the method for producing an adhesive substrate as defined in [13], forming a substrate containing any of them, and forming a metal layer on one or both surfaces of said substrate to obtain a metal laminate.
[15] A method for producing a printed circuit board, comprising obtaining a metal laminate by the method for producing a metal laminate as defined in [14], and etching the metal layer to form a pattern circuit to obtain a printed circuit board.

### Advantageous Effects of Invention

According to the method for producing a liquid composition of the present invention, agglomeration of the resin powder is suppressed even at a low viscosity, and it is possible to obtain a uniformly dispersed liquid composition. According to the production methods of the present invention, it is possible to obtain a film, a fiber-reinforced film, a prepreg, an adhesive substrate, a metal laminate and a printed circuit board, in which the resin powder is uniformly dispersed and which are excellent in electrical properties.

### DESCRIPTION OF EMBODIMENTS

In this specification, meanings of the following terms are as follows. The “dielectric constant” is a value measured at a frequency of 2.5 GHz by the SPDR (Split Post Dielectric Resonator) method, in an environment in ranges of 23° C.±2° C. and RH 50±5%.

A “unit” in a polymer means an atomic group derived from one molecule of a monomer formed by polymerization of the monomer. A unit may be an atomic group formed directly by the polymerization reaction or may be an atomic group having a portion of such an atomic group converted to another structure by treating the polymer obtained by the polymerization reaction.

A “(meth)acrylate” is a general term for an acrylate and a methacrylate. Similarly, “(meth)acryloyl” is a general term for acryloyl and methacryloyl.

### [Method for Producing Liquid Composition]

The method for producing a liquid composition of the present invention is a method which comprises heat-treating a mixture comprising a resin powder having an average particle size of from 0.02 to 200 μm made of a powder material containing a polymer (X), a binder component having a reactive group reactive with the functional group of the resin powder, and a liquid medium capable of dissolving the binder component, to obtain a liquid composition, of which the viscosity change rate to the viscosity before heating is from 5 to 200%.

The resin powder is a resin powder having an average particle size of from 0.02 to 200 μm made of a powder material containing a polymer (X).

The polymer (X) contained in the powder material may be one type, or two or more types.

The powder material may further contain, as the case requires, a resin other than the polymer (X) within a range not to impair the effects of the present invention.

The polymer (X) is a fluorinated polymer containing units (hereinafter referred to as “TFE units”) based on tetrafluoroethylene (hereinafter referred to as “TFE”) and having at least one functional group (hereinafter referred to also as “functional group (i)”) selected from the group consisting of a carbonyl group-containing group, a hydroxy group, an epoxy group and an isocyanate group.

The functional group (i) may be contained in a unit in the polymer (X), and in such a case, the unit having the functional group (i) may be a unit having a fluorine atom, or may be a unit having no fluorine atom. Hereinafter, a unit having a functional group (i) may be referred to as a “unit (1)”. The unit (1) is preferably a unit having no fluorine atom.

Otherwise, the functional group (i) may be contained in a terminal group of the main chain of the polymer (X), and in such a case, the polymer (X) may have or may not have a unit (1). The terminal group having a functional group (i) is a terminal group derived from a polymerization initiator, a chain transfer agent, etc., and the terminal group having a functional group (i) is formed by using a polymerization initiator or a chain transfer agent which has a functional group (i), or which forms a functional group (i) at the time of the reaction to form a polymer. It is also possible that after forming a polymer, a functional group (i) may be introduced into its terminal group. As the functional group (i) contained in the terminal group, an alkoxycarbonyl group, a carbonate group, a carboxy group, a fluoroformyl group, an acid anhydride residual group, or a hydroxy group is preferred.

The polymer (X) is preferably a copolymer having units (1) and TFE units. Further, in such a case, the polymer (X) may further have, as the case requires, units other than the units (1) and TFE units. The units other than the units (1) and TFE units, are preferably perfluoro units such as PAVE units or HFP units as described below.

Hereinafter, the present invention will be described with reference to a polymer (X) being a copolymer having units (1) and TFE units, as an example.

The carbonyl group-containing group in the functional group (i) is not particularly limited as long as it is a group containing a carbonyl group in its structure, and may, for example, be a group having a carbonyl group between carbon atoms of a hydrocarbon group, a carbonate group, a carboxy group, a haloformyl group, an alkoxycarbonyl group, an acid anhydride residual group, a polyfluoroalkoxycarbonyl group, a fatty acid residual group, etc. Among them, with a view to improving mechanical pulverization properties and improving adhesion to a metal, preferred are a group having a carbonyl group between carbon atoms of a hydrocarbon group, a carbonate group, a carboxy group, a haloformyl group, an alkoxycarbonyl group and an acid anhydride residual group, and more preferred are a carboxy group and an acid anhydride residual group.

The hydrocarbon group in the group having a carbonyl group between carbon atoms of a hydrocarbon group, may, for example, be an alkylene group having from 2 to 8 carbon atoms. The number of carbon atoms in the alkylene group is the number of carbon atoms at the portion other than the carbonyl group in the alkylene group. The alkylene group may be linear or branched.

The haloformyl group is a group represented by —C(═O)—X (wherein X is a halogen atom). As the halogen atom in the haloformyl group, a fluorine atom, a chlorine atom, etc. may be mentioned, and a fluorine atom is preferred. That is, as the haloformyl group, a fluoroformyl group (referred to also as a carbonyl fluoride group) is preferred.

The alkoxy group in the alkoxycarbonyl group may be linear or branched. As the alkoxy group, an alkoxy group having from 1 to 8 carbon atoms is preferred, and a methoxy group or an ethoxy group is particularly preferred.

The units (1) are preferably units based on a monomer (hereinafter referred to also as a “monomer (m1)”) having a functional group (i). The number of functional groups (i) which the monomer (m1) has, may be one, or two or more. In a case where the monomer (m1) has 2 or more functional groups (i), such functional groups (i) may be the same or different from one another.

As the monomer (m1), preferred is a compound having one functional group (i) and one polymerizable double bond.

As the monomer (m1), one type may be used alone, or two or more types may be used in combination.

Among the monomers (m1), a monomer having a carbonyl group-containing group may, for example, be a cyclic hydrocarbon compound having an acid anhydride residual group and a polymerizable unsaturated bond (hereinafter referred to also as a “monomer (m11)”), a monomer having a carboxy group (hereinafter referred to also as a “monomer (m12)”), a vinyl ester, a (meth)acrylate, CF₂═CFOR^{f1}COOX¹ (wherein R^{f1} is a C₁₋₁₀ perfluoroalkylene group which may contain an etheric oxygen atom, and X¹ is a hydrogen atom or a C₁₋₃ alkyl group), etc.

The monomer (m11) may, for example, be an acid anhydride of an unsaturated dicarboxylic acid, etc. The acid anhydride of an unsaturated dicarboxylic acid may, for example, be itaconic anhydride (hereinafter referred to also as “IAH”), citraconic anhydride (hereinafter referred to also as “CAH”), 5-norbornene-2,3-dicarboxylic anhydride (another name: himic anhydride, hereinafter referred to also as “NAH”), maleic anhydride, etc.

The monomer (m12) may, for example, be an unsaturated dicarboxylic acid such as itaconic acid, citraconic acid, 5-norbornene-2,3-dicarboxylic acid, maleic acid, etc.; an unsaturated monocarboxylic acid such as acrylic acid, methacrylic acid, etc.; etc.

The vinyl ester may, for example, be vinyl acetate, vinyl chloroacetate, vinyl butanoate, vinyl pivalate, vinyl benzoate, etc.

The (meth)acrylate may, for example, be a (polyfluoroalkyl) acrylate, a (polyfluoroalkyl) methacrylate, etc.

The monomer containing a hydroxy group may, for example, be a compound which is a vinyl ester, a vinyl ether, an allyl ether, or an unsaturated carboxylic acid ester (a (meth)acrylate, a crotonic acid ester, etc.) and which has at least one hydroxy group at its terminal or in its side chain, or an unsaturated alcohol. Specifically, for example, 2-hydroxyethyl (meth)acrylate, 2-hydroxyethyl crotonate, allyl alcohol, etc. may be mentioned.

The monomer containing an epoxy group may, for example, be an unsaturated glycidyl ether (e.g. allyl glycidyl ether, 2-methylallyl glycidyl ether, vinyl glycidyl ether, etc.), an unsaturated glycidyl ester (e.g. glycidyl acrylate, glycidyl methacrylate, etc.), etc.

The monomer containing an isocyanate group may, for example, be 2-(meth)acryloyloxyethyl isocyanate, 2-(2-(meth)acryloyloxyethoxy)ethyl isocyanate, 1,1-bis((meth)acryloyloxymethyl)ethyl isocyanate, etc.

The unit (1) preferably has, with a view to improving mechanical pulverization properties and improving adhesion to a metal, at least a carbonyl group-containing group as the functional group (i). The monomer (m1) is preferably a monomer having a carbonyl group-containing group.

As the monomer having a carbonyl group-containing group, from the viewpoint of thermal stability and improving adhesion to a metal, the monomer (m11) is preferred. Among them, IAH, CAH and NAH are particularly preferred. When at least one member selected from the group consisting of IAH, CAH and NAH is used, it is possible to easily produce a fluorinated copolymer containing an acid anhydride residual group without using a special polymerization method which is required when using maleic anhydride (see JP-A-H11-193312). Among IAH, CAH and NAH, from such a viewpoint that adhesion with the binder component will be more excellent, NAH is preferred.

The polymer (X) may have, as units other than the units (1) and TFE units, units (hereinafter referred to as “PAVE units”) based on a perfluoro(alkyl vinyl ether) (hereinafter referred to also as “PAVE”).

PAVE may, for example, be CF₂═CFOR^{f2} (wherein R^{f2} is a C₁₋₁₀ perfluoroalkyl group which may contain an etheric oxygen atom). The perfluoroalkyl group in R^{f2} may be linear or branched. The number of carbon atoms in R^{f2} is preferably from 1 to 3.

CF₂═CFOR^{f2} may be CF₂═CFOCF₃, CF₂═CFOCF₂CF₃, CF₂═CFOCF₂CF₂CF₃ (hereinafter referred to also as “PPVE”), CF₂═CFOCF₂CF₂CF₂CF₃, CF₂═CFO(CF₂)₈F, etc., and PPVE is preferred.

As PAVE, one type may be used alone, or two or more types may be used in combination.

The polymer (X) may have, as units other than the units (1) and TFE units, units (hereinafter referred to as “HFP units”) based on hexafluoropropylene (hereinafter referred to also as “HFP”).

The polymer (X) may have, as units other than the units (1) and TFE units, units (hereinafter referred to as “other units”) other than PAVE units and HFP units.

Such other units may be units based on a fluorinated monomer (but excluding the monomer (m1), TFE, PAVE and HFP) or units based on a non-fluorinated monomer (but excluding the monomer (m1)).

The above fluorinated monomer is preferably a fluorinated compound having one polymerizable double bond, and may, for example, be a fluoroolefin (but excluding TFE and HFP) such as vinyl fluoride, vinylidene fluoride, trifluoroethylene, chlorotrifluoroethylene, etc., CF₂═CFOR^{f3}SO₂X³ (wherein R^{f3} is a C₁₋₁₀ perfluoroalkylene group, or a C₂₋₁₀ perfluoroalkylene group containing an etheric oxygen atom, and X³ is a halogen atom or a hydroxy group), CF₂═CF(CF₂)ₚOCF═CF₂ (wherein p is 1 or 2), CH₂═CX⁴(CF₂)_{q}X⁵ (wherein X⁴ is a hydrogen atom or a fluorine atom, q is an integer of from 2 to 10, and X⁵ is a hydrogen atom or a fluorine atom), a perfluoro(2-methylene-4-methyl-1,3-dioxolane), etc. One of these may be used alone, or two or more of them may be used in combination.

As the above fluorinated monomer, vinylidene fluoride, chlorotrifluoroethylene and CH₂═CX⁴(CF₂)_{q}X⁵ are preferred.

CH₂═CX⁴(CF₂)_{q}X⁵ may be CH₂═CH(CF₂)₂F, CH₂═CH(CF₂)₃F, CH₂═CH(CF₂)₄F, CH₂═CF(CF₂)₃H, CH₂═CF(CF₂)₄H, etc., and CH₂═CH(CF₂)₄F or CH₂═CH(CF₂)₂F is preferred.

The above non-fluorinated monomer is preferably a non-fluorinated compound having one polymerizable double bond, and may, for example, be an olefin having at most 3 carbon atoms, such as ethylene, propylene, etc. One of these may be used alone, or two or more of them may be used in combination.

As the monomer (m42), ethylene or propylene is preferred, and ethylene is particularly preferred.

As the above fluorinated monomer or the above non-fluorinated monomer, one type may be used alone, or two or more types may be used in combination.

Otherwise, the above fluorinated monomer and the above non-fluorinated monomer may be used in combination.

As the polymer (X), the polymer (X-1) and polymer (X-2) as described below, are preferred, and the polymer (X-1) is particularly preferred.

The polymer (X-1) is a copolymer having units (1), TFE units and PAVE units, wherein to the total of all units, the proportion of units (1) is from 0.01 to 3 mol %, the proportion of TFE units is from 90 to 99.89 mol %, and the proportion of PAVE units is from 0.1 to 9.99 mol %.

The polymer (X-1) may further have, as the case requires, at least one of HFP units and other units. The polymer (X-1) may be one consisting of units (1), TFE units and PAVE units, may be one consisting of units (1), TFE units, PAVE units and HFP units, may be one consisting of units (1), TFE units, PAVE units and other units, or may be one consisting of units (1), TFE units, PAVE units, HFP units and other units.

The polymer (X-1) is preferably a copolymer having units based on a monomer containing a carbonyl group-containing group, TFE units and PAVE units, particularly preferably a copolymer having units based on the monomer (m11), TFE units and PAVE units. Preferred specific examples of the polymer (X-1) may be a TFE/PPVE/NAH copolymer, a TFE/PPVE/IAH copolymer, a TFE/PPVE/CAH copolymer, etc.

The polymer (X-1) may have a functional group (i) as a terminal group. The functional group (i) can be introduced by suitably selecting a radical polymerization initiator, a chain transfer agent, etc. to be used at the time of the production of the polymer (X-1).

The proportion of units (1) to the total of all units constituting the polymer (X-1) is from 0.01 to 3 mol %, preferably from 0.03 to 2 mol %, particularly preferably from 0.05 to 1 mol %. When the content of units (1) is at least the lower limit value in the above range, a resin powder having a large bulk density will be easily obtained. Further, the adhesion between the resin powder and the binder component, and the interlayer adhesion between a film, etc. formed by the liquid composition and another material (metal, etc.) will be excellent. When the content of units (1) is at most the upper limit value in the above range, the heat resistance, color, etc. of the polymer (X-1) will be excellent.

The proportion of TFE units to the total of all units constituting the polymer (X-1) is from 90 to 99.89 mol %, preferably from 95 to 99.47 mol %, particularly preferably from 96 to 98.95 mol %. When the content of TFE units is at least the lower limit value in the above range, the polymer (X-1) will be excellent in electric characteristics (low dielectric constant, etc.), heat resistance, chemical resistance, etc. When the content of TFE units is at most the upper limit value in the above range, the polymer (X-1) will be excellent in melt-moldability, stress crack resistance, etc.

The proportion of PAVE units to the total of all units constituting the polymer (X-1) is from 0.1 to 9.99 mol %, preferably from 0.5 to 9.97 mol %, particularly preferably from 1 to 9.95 mol %. When the content of PAVE units is within the above range, the polymer (X-1) will be excellent in moldability.

The total proportion of units (1), TFE units and PAVE units to the total of all units in the polymer (X-1), is preferably at least 90 mol %, more preferably at least 95 mol %, further preferably at least 98 mol %. The upper limit of the total proportion is not particularly limited and may be 100 mol %.

The contents of the respective units in the polymer (X-1) can be measured by an NMR analysis such as a molten nuclear magnetic resonance (NMR) analysis, a fluorine content analysis, an infrared absorption spectrum analysis, etc. For example, as described in JP-A-2007-314720, by using a method such as an infrared absorption spectrum analysis, it is possible to obtain the proportion (mol %) of units (1) in all units constituting the polymer (X-1).

The polymer (X-2) is a copolymer having units (1), TFE units and HFP units, wherein to the total of all units, the proportion of units (1) is from 0.01 to 3 mol %, the proportion of TFE units is from 90 to 99.89 mol %, and the proportion of HFP units is from 0.1 to 9.99 mol % (but excluding the polymer (X-1)).

The polymer (X-2) may further have, as the case requires, PAVE units and other units. The polymer (X-2) may be one consisting of units (1), units (2) and HFP units, may be one consisting of units (1), TFE units, HFP units and PAVE units (but excluding the polymer (X-1)), may be one consisting of units (1), TFE units, HFP units and other units, or may be one consisting of units (1), TFE units, HFP units, PAVE units and other units (but excluding the polymer (X-1)).

The polymer (X-2) is preferably a copolymer having units based on a monomer containing a carbonyl group-containing group, TFE units and HFP units, particularly preferably a copolymer having units based on the monomer (m11), TFE units and HFP units. Preferred specific examples of the polymer (X-2) may be a TFE/HFP/NAH copolymer, a TFE/HFP/IAH copolymer, a TFE/HFP/CAH copolymer, etc.

Further, the polymer (X-2) may have, like the polymer (X-1), a terminal group having a functional group (i).

The proportion of units (1) to the total of all units constituting the polymer (X-2) is from 0.01 to 3 mol %, preferably from 0.02 to 2 mol %, particularly preferably from 0.05 to 1.5 mol %. When the content of units (1) is at least the lower limit value in the above range, a resin powder having a large bulk density is easily obtainable. Further, the adhesion between the resin powder and the binder component, and the interlayer adhesion between a film, etc. formed by the liquid composition and another material (metal, etc.), will be excellent. When the content of units (1) is at most the upper limit value in the above range, the heat resistance, color, etc. of the polymer (X-2) will be excellent.

The proportion of TFE units to the total of all units constituting the polymer (X-2) is from 90 to 99.89 mol %, preferably from 91 to 98 mol %, particularly preferably from 92 to 96 mol %. When the content of TFE units is at least the lower limit value in the above range, the polymer (X-2) will be excellent in electric characteristics (low dielectric constant, etc.), heat resistance, chemical resistance, etc. When the content of TFE units is at most the upper limit value in the above range, the polymer (X-2) will be excellent in melt-moldability, stress crack resistance, etc.

The proportion of HFP units to the total of all units constituting the polymer (X-2) is from 0.1 to 9.99 mol %, preferably from 1 to 9 mol %, particularly preferably from 2 to 8 mol %. When the content of HFP units is within the above range, the polymer (X-2) will be excellent in moldability.

The total proportion of units (1), TFE units and HFP units to the total of all units in the polymer (X-2) is preferably at least 90 mol %, more preferably at least 95 mol %, further preferably at least 98 mol %. The upper limit of the total proportion is not particularly limited and may be 100 mol %.

The melting point of the polymer (X) is preferably from 260 to 380° C. When the melting point of the polymer (X) is at least 260° C., the polymer will be excellent in heat resistance. When the melting point of the polymer (X) is at most 380° C., it will be excellent in moldability. Particularly, a problem of e.g. surface irregularities due to particles after molding will be less likely to occur.

Further, the polymer (X) is preferably melt-moldable. Here, being “melt-moldable” is meant to show melt flowability. Here, “show melt flowability” means that under a condition of a load of 49N and at a temperature higher by at least 20° C. than the melting point of the resin, there is a temperature at which the melt flow rate becomes to be from 0.1 to 1,000 g/10 min. The “melt flow rate” means the melt mass flow rate (MFR) as defined in JIS K7210; 1999 (ISO 1133; 1997). The melting point of the melt-moldable polymer (X) is more preferably from 260 to 320° C., further preferably from 280 to 320° C., particularly preferably from 295 to 315° C., most preferably from 295 to 310° C. When the melting point of the polymer (X) is at least the lower limit value in the above range, it will be excellent in heat resistance. When the melting point of the polymer (X) is at most the upper limit value in the above range, it will be excellent in melt moldability.

Further, the melting point of the polymer (X) can be adjusted by the types or contents of units constituting the polymer (X), the molecular weight, etc. For example, as the proportion of TFE unit is increased, there is a tendency that the melting point becomes high.

MFR of the polymer (X) is preferably from 0.1 to 1,000 g/10 min, more preferably from 0.5 to 100 g/10 min, further preferably from 1 to 30 g/10 min, particularly preferably from 5 to 20 g/10 min. When MFR is at least the lower limit value in the above range, the polymer (X) will be excellent in moldability, and a film, etc. formed by using the liquid composition will be excellent in surface smoothness and outer appearance. When MFR is at most the upper limit value in the above range, the polymer (X) will be excellent in mechanical strength, and a film, etc. formed by using the liquid composition will be excellent in mechanical strength.

MFR is an index for the molecular weight of the polymer (X), i.e. the larger the MFR, the smaller the molecular weight, and the smaller the MFR, the larger the molecular weight. The molecular weight, accordingly MFR, of the polymer (X) can be adjusted by conditions for producing the polymer (X). For example, if the polymerization time is shortened in the polymerization of the monomer, MFR tends to increase.

The dielectric constant of the polymer (X) is preferably at most 2.5, more preferably at most 2.4, particularly preferably from 2.0 to 2.4. As the dielectric constant of the polymer (X) is low, the electrical characteristics of a film, etc. formed by using the liquid composition will be more excellent, and, for example, in the case of using the film as a substrate for a printed circuit board, an excellent transmission efficiency can be obtained.

The dielectric constant of the copolymer (X) can be adjusted by the content of TFE units.

The polymer (X) may be produced by a conventional method. For example, as a method for producing the polymer (X), a method described in [0053] to [0060] of WO2016/017801 may be mentioned.

The resin other than the polymer (X) which may be contained in the powder material is not particularly limited so long as it does not impair the characteristics of electrical reliability, and, for example, a fluorinated polymer other than the polymer (X), an aromatic polyester, a polyamideimide, a thermoplastic polyimide, etc. may be mentioned. As such a resin, from the viewpoint of electrical reliability, a fluorinated polymer other than the polymer (X) is preferred. As the resin, one type may be used alone, or two or more types may be used in combination.

The fluorinated copolymer other than the polymer (X) may, for example, be polytetrafluoroethylene, a tetrafluoroethylene/perfluoroalkyl vinyl ether copolymer (but excluding the polymer (X)), a tetrafluoroethylene/hexafluoropropylene copolymer (but excluding the polymer (X)), an ethylene/tetrafluoroethylene copolymer, etc. As the fluorinated polymer other than the polymer (X), from the viewpoint of heat resistance, preferred is one having a melting point of at least 280° C.

The powder material is preferably such that the polymer (X) is the main component. When the polymer (X) is the main component, a resin powder having a high bulk density tends to be readily obtainable. The larger the bulk density of the resin powder, the better the handling efficiency. Here, the powder material being such that “the main component is the polymer (X)”, means that the proportion of the polymer (X) to the total amount of the powder material is at least 80 mass %. The proportion of the polymer (X) to the total amount of the powder material is preferably at least 85 mass %, more preferably at least 90 mass %, particularly preferably 100 mass %. The average particle size of the resin powder is from 0.02 to 200 μm, preferably from 0.05 to 100 μm, more preferably from 0.1 to 50 μm, further preferably from 0.02 to 30 μm, particularly preferably from 0.02 to 10 μm. As the average particle size of the resin powder is smaller, it is possible to increase the filling rate of the resin powder to the binder component. The higher the filling rate, the better the electrical characteristics (the low dielectric constant, etc.) of a film, etc. formed by using the liquid composition. Further, as the average particle size of the resin powder is smaller, the thickness of a film or fiber-reinforced film formed by using the liquid composition can be made thinner, and, for example, can be easily made thin so as to be useful for application to a flexible printed circuit board.

The average particle size of the resin powder is a volume-based cumulative 50% diameter (D50) obtainable by a laser diffraction scattering method. That is, the particle size distribution is measured by a laser diffraction scattering method, whereupon a cumulative curve is obtained based on the total volume of the population of particles being 100%, and the particle diameter at the point where the cumulative volume on that cumulative curve becomes 50% is adopted.

In the case of producing a film having a thickness of at most 50 μm by using the liquid composition, the resin powder preferably has an average particle size of from 0.02 to 6 μm and a D90 of at most 8 μm, more preferably has an average particle size of from 0.02 to 5 μm and a D90 of at most 6 μm.

D90 of the resin powder is a volume-based cumulative 90% diameter obtainable by a laser diffraction scattering method. That is, the particle size distribution is measured by a laser diffraction scattering method, whereupon a cumulative curve is obtained based on the total volume of the population of particles being 100%, and the particle diameter at the point where the cumulative volume on that cumulative curve becomes 90% is adopted.

When the average particle size of the resin powder is more than 10 μm and at most 50 μm, the loosely packed bulk density of the resin powder is preferably at least 0.18 g/mL, more preferably from 0.18 to 0.85 g/mL, particularly preferably from 0.2 to 0.85 g/m L. When the average particle size of the resin powder is from 0.02 to 10 μm, the loosely packed bulk density of the resin powder is preferably at least 0.05 g/mL, more preferably from 0.05 to 0.5 g mL, particularly preferably from 0.08 to 0.5 g/mL.

When the average particle size of the resin powder is more than 10 μm and at most 50 μm, the densely packed bulk density of the resin powder is preferably at least 0.25 g/mL, more preferably from 0.25 to 0.95 g/mL, particularly preferably from 0. 4 to 0.95 g/m L. When the average particle size of the resin powder is from 0.02 to 10 μm, the densely packed bulk density of the resin powder is preferably at least 0.05 g/mL, more preferably from 0.05 to 0.8 g/mL, particularly preferably from 0.1 to 0.8 g/mL.

The larger the loosely packed bulk density or the densely packed bulk density, the better the handling efficiency of the resin powder. Further, it is possible to increase the filling rate of the resin powder to the binder component. When the loosely packed bulk density or the densely packed bulk density is at most the upper limit value in the above range, it can be used in a common process.

As a method for producing a resin powder, a method may be mentioned in which a powder material containing a polymer (X) obtained by polymerization or a commercially available polymer (X), is, if necessary after pulverization, classified (sieved, etc.) to obtain a resin powder having an average particle size of from 0.02 to 200 μm. In a case where the polymer (X) is produced by solution polymerization, suspension polymerization or emulsion polymerization, after recovering particulate polymer (X) by removing the organic solvent or aqueous medium used for the polymerization, pulverization and classification (sieving, etc.) are conducted. In a case where the average particle size of the polymer (X) obtained by the polymerization is from 0.02 to 200 μm, such polymer (X) can be used as it is, as the resin powder.

In a case where the powder material contains a resin other than the polymer (X), it is preferred to melt-knead the polymer (X) and the resin, followed by pulverization and classification.

As the pulverization method and the classification method for the powder material, the methods described in [0065] to [0069] of WO2016/017801 may be employed.

Further, as the resin powder, if a desired resin powder is commercially available, such a commercially available resin powder may be used.

The binder component has a reactive group that reacts with the functional group (i) of the resin powder. The reactive group is selected depending on the functional group (i) of the resin powder to be combined. The reactive group may be a carbonyl group-containing group, a hydroxy group, an amino group, an epoxy group, etc.

The binder component having a reactive group may, for example, be a polyamic acid being a linear polyimide or crosslinked polyimide precursor, an epoxy resin, a curable acrylic resin, a phenol resin, a curable polyester resin, a bismaleimide resin, a modified polyphenylene ether resin, a fluororesin having a reactive group (but excluding a polymer (X)), etc. As the binder component, a polyamic acid, an epoxy resin, a modified polyphenylene ether resin and a bismaleimide resin are preferred. As the binder component, one type may be used alone, or two or more types may be used in combination.

As a binder component to become a resin having a melting point such as a linear polyimide, preferred is one whereby the melting point of the resin having a melting point will be at least 280° C. Thus, in a film, etc. formed by the liquid composition, swelling (foaming) due to heat can easily be prevented when exposed to an atmosphere corresponding to solder reflow.

In a case where in a curable resin, the group contributing to the curing reaction and the above reactive group are common (e.g. the epoxy group in an epoxy resin), the binder component has reactive groups in a total amount of the reactive group reactive with the functional group (i) and the reactive group contributing to the curing reaction. Usually, the amount of the reactive group reactive with the functional groups (i) is relatively small, and therefore, it is considered sufficient that the curable resin contains reactive groups in an amount necessary for the curing. Similarly in a polyamic acid, even if some of its carboxy groups react with the reactive groups, such does not disturb the formation of the polyimide.

In other words, in a case where the binder component has many reactive groups, by letting a suitable amount of the reactive groups be reacted with functional groups (i) in the reaction with the functional groups (i), the viscosity change rate of the liquid composition in the present invention is adjusted to be within a predetermined numerical range.

A polyamic acid is a polymer having a carboxy group as a reactive group, and it is considered that in some cases, a >NH group may also function as a reactive group.

As the polyamic acid being a linear polyimide or crosslinked polyimide precursor, preferred is a wholly aromatic polyamic acid obtainable by condensation polymerization of an aromatic polyamine such as an aromatic diamine, and an aromatic polycarboxylic dianhydride or a derivative thereof. By further condensation polymerization of the wholly aromatic polyamic acid, a wholly aromatic polyimide is obtainable.

Specific examples of the aromatic polycarboxylic dianhydride and the aromatic diamine may be those described in [0055] and [0057] of JP-A-2012-145676. One of them may be used alone, or two or more of them may be used in combination.

The polyamine to form a polyamic acid may, specifically be, for example, 4,4′-diaminodiphenyl ether, 3,4′-diaminodiphenyl ether, 1,3-bis(4-aminophenoxy)benzene, 1,4-bis(4-aminophenoxy)benzene, p-phenylenediamine, 4,4′-diaminodiphenylpropane, 4,4′-diaminodiphenylmethane, benzidine, 3,3′-dichlorobenzidine, 4,4′-diaminodiphenyl sulfide, 3,3′-diaminodiphenyl sulfone, 4,4′-diaminodiphenyl sulfone, 4,4′-diaminodiphenyl ether, 3,3′-diaminodiphenyl ether, 3,4′-diaminodiphenyl ether, 1,5-diaminonaphthalene, 4, 4′-diaminodiphenyl diethyl silane, 4,4′-diaminodiphenyl silane, 4,4′-diaminodiphenyl ethyl phosphine oxide, 4,4′-diaminodiphenyl N-methylamine, 4,4′-diaminodiphenyl N-phenylamine, 1,4-diaminobenzene (p-phenylenediamine), 1,3-diaminobenzene, 1,2-diaminobenzene, 2,2-bis[4-(4-aminophenoxy)phenyl]propane, and derivatives thereof. Among them, 4,4′-diaminodiphenyl ether or 2,2-bis[4-(4-aminophenoxy)phenyl] propane, is preferred.

The polycarboxylic dianhydride or a derivative thereof to form a polyamic acid, may specifically be, for example, pyromellitic dianhydride, 2,3,6,7-naphthalene tetracarboxylic dianhydride, 3,3′,4,4′-biphenyl tetracarboxylic acid dianhydride, 1,2,5,6-naphthalene tetracarboxylic dianhydride, 2,2′,3,3′-biphenyl tetracarboxylic dianhydride, 3,3′,4,4′-benzophenone tetracarboxylic dianhydride, 2,2-bis(3,4-dicarboxyphenyl) propane dianhydride, 3,4,9,10-perylene tetracarboxylic dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, oxydiphthalic dianhydride, bis(3,4-dicarboxyphenyl)sulfone dianhydride, p-phenylene bis(trimellitic acid monoester acid anhydride), ethylene bis(trimellitic acid monoester acid anhydride), bisphenol A bis(trimellitic acid monoester acid anhydride), and their derivatives. Among them, pyromellitic dianhydride, 3,3′,4,4′-biphenyl tetracarboxylic dianhydride, or 3,3′,4,4′-benzophenone tetracarboxylic dianhydride is preferred.

An epoxy resin means a compound having at least two epoxy groups, which is also referred to as a main agent. In the case of curing an epoxy resin, it is reacted with a curing agent for an epoxy resin.

The epoxy resin may, for example, be a cresol novolak type epoxy resin, a bisphenol A type epoxy resin, a bisphenol F type epoxy resin, a phenol novolak type epoxy resin, an alkylphenol novolak type epoxy resin, a biphenol F type epoxy resin, a naphthalene type epoxy resin, a dicyclopentadiene type epoxy resin, an epoxidized condensation product of a phenol and an aromatic aldehyde having a phenolic hydroxy group, a triglycidyl isocyanurate, an alicyclic epoxy resin, etc. As the epoxy resin, one type may be used alone, or two or more types may be used in combination.

The weight average molecular weight of the epoxy resin is preferably from 100 to 1,000,000, more preferably from 1,000 to 100,000. When the weight average molecular weight of the epoxy resin is within the above range, interlayer adhesion of a film, etc. formed by the liquid composition and another material (such as metal) will be excellent.

The weight average molecular weight of the epoxy resin is measured by gel permeation chromatography (GPC).

The bismaleimide resin may, for example, be a resin composition (BT resin) using a bisphenol A type cyanate ester resin and a bismaleimide compound in combination, as described in JP-A-H7-70315, or one disclosed in the invention and its background art in WO2013/008667.

### (Liquid Medium)

As the liquid medium capable of dissolving the binder component, a known liquid medium may be used depending upon the type of the binder component, and, for example, N,N-dimethylformamide, N,N-dimethylacetamide, N-methyl-2-pyrrolidone, N-ethyl-2-pyrrolidone, N-methyl caprolactam, dimethyl sulfoxide, tetramethylurea, pyridine, dimethylsulfone, hexamethyl sulfoxide, γ-butyrolactone, isopropyl alcohol, methoxymethyl pentanol, dipentene, ethyl amyl ketone, methyl nonyl ketone, methyl ethyl ketone, methyl isoamyl ketone, methyl isopropyl ketone, methyl cellosolve, ethyl cellosolve, methyl cellosolve acetate, ethyl cellosolve acetate, butyl carbitol, ethyl carbitol, ethylene glycol, ethylene glycol monoacetate, ethylene glycol monoisopropyl ether, ethylene glycol monobutyl ether, propylene glycol, propylene glycol monoacetate, propylene glycol monomethyl ether, propylene glycol-tert-butyl ether, dipropylene glycol monomethyl ether, diethylene glycol, diethylene glycol monoacetate, diethylene glycol dimethyl ether, diethylene glycol mono-n-butyl ether, dipropylene glycol monoacetate monomethyl ether, dipropylene glycol monomethyl ether, dipropylene glycol monoethyl ether, dipropylene glycol monoacetate monoethyl ether, dipropylene glycol monopropyl ether, dipropylene glycol monoacetate monopropyl ether, 3-methyl-3-methoxybutyl acetate, tripropylene glycol methyl ether, 3-methyl-3-methoxybutanol, diisopropyl ether, ethyl isobutyl ether, diisobutylene, amyl acetate, butyl butyrate, butyl ether, diisobutyl ketone, methylcyclohexane, propyl ether, dihexyl ether, dioxane, n-hexane, n-pentane, n-octane, diethyl ether, cyclohexanone, ethylene carbonate, propylene carbonate, methyl lactate, ethyl lactate, methyl acetate, ethyl acetate, n-butyl acetate, propylene acetate glycol monoethyl ether, 2-(2-n-butoxyethoxy)ethyl acetate, methyl pyruvate, ethyl pyruvate, methyl 3-methoxypropionate, methylethyl 3-ethoxypropionate, ethyl 3-methoxypropionate, 3-ethoxypropionic acid, 3-methoxypropionic acid, propyl 3-methoxy propionate, butyl 3-methoxy propionate, diglyme, 4-hydroxy-4-methyl-2-pentanone, 3-methoxy-N,N-dimethylpropanamide, 3-ethoxy-N,N-dimethylpropanamide, 3-butoxy-N,N-dimethylpropanamide, etc. may be mentioned. As the liquid medium, one type may be used alone, or two or more types may be used in combination.

The mixture comprising a resin powder, a binder component and a liquid medium may further contain a filler. When the mixture contains a filler, the dielectric constant and dielectric loss tangent of a film, etc. formed by using the liquid composition can be made to be low. As the filler, an inorganic filler is preferred, and those described in [0089] of WO2016/017801 may be mentioned. As the inorganic filler, one type may be used alone, or two or more types may be used in combination.

The mixture may also contain a surfactant. The surfactant is not particularly limited, and may be a nonionic surfactant, an anionic surfactant, a cationic surfactant, etc. As the surfactant, one type may be used alone, or two or more types may be used in combination.

The content of the resin powder in the mixture is, to 100 parts by mass of the binder component, preferably from 5 to 500 parts by mass, more preferably from 10 to 400 parts by mass, particularly preferably from 20 to 300 parts by mass. When the content of the resin powder is at least the lower limit value in the above range, a film, etc. formed by using the liquid composition will be excellent in electric characteristics. When the content of the resin powder is at most the upper limit value in the above range, the resin powder will be easily uniformly dispersed in the liquid composition, and a film, etc. formed by using the liquid composition will be excellent in mechanical strength.

The content of the liquid medium in the mixture is, to 100 parts by mass in total of the resin powder and the binder component, preferably from 1 to 1,000 parts by mass, more preferably from 10 to 500 parts by mass, particularly preferably from 30 to 250 parts by mass. When the content of the liquid medium is at least the lower limit value in the above range, the viscosity of the mixture will not be too high, and coating properties at the time of film formation will be good. When the content of the liquid medium is at most the upper limit value in the above range, the viscosity of the mixture will not be too low, and coating properties at the time of film formation will be good, and further, since the amount of the liquid medium to be used, will be small, a defective appearance of a film product derived from the step of removing the liquid medium tends to be less likely to occur.

In a case where the mixture contains a filler, the content of the filler in the mixture is, to 100 parts by mass of the binder component, preferably from 0.1 to 100 parts by mass, more preferably from 0.1 to 60 parts by mass.

In a case where the mixture contains a surfactant, the content of the surfactant in the mixture is, to 100 parts by mass of the binder component, preferably from 0.1 to 20 parts by mass, more preferably from 0.3 to 7 parts by mass.

The heat treatment of the mixture comprising the resin powder, the binder component and the liquid medium is carried out to the mixture, so that the viscosity change rate after heating from the viscosity before heating becomes to be from 5 to 200%. It is thereby possible to suppress the resin powder from agglomerating in the obtained liquid composition.

The viscosity change rate by the heat treatment of the mixture is from 5 to 200%, preferably from 7 to 180%, more preferably from 10 to 160%, further preferably from 15 to 140%. When the viscosity change rate is at least the lower limit value in the above range, it is possible to suppress the agglomeration of the resin powder in the liquid composition. When the viscosity change rate is at most the upper limit value in the above range, film forming properties of the liquid composition can be sufficiently secured.

The method for heat treatment is not particularly limited, and, for example, heating by a jacket while stirring the mixture, or heating by introducing a heater directly in the mixture may be mentioned.

The heating temperature may be suitably set, depending on the types of the resin powder and the binder component, so that the viscosity change rate falls within the above range. For example, in the case of a mixture comprising a resin powder containing a polymer (X) having an acid anhydride residual group, and an epoxy resin as the binder component, the heating temperature may be made to be from 35 to 110° C.

The heating time may be suitably set, depending on the types of the resin powder and the binder component, so that the viscosity change rate falls within the above range, and, for example, it may be made to be from 1 to 300 minutes.

In the case of using a thermosetting resin as the binder component, a curing agent may be added to the liquid composition after the heat treatment. As the curing agent, a thermosetting agent (a melamine resin, a urethane resin, etc.), a curing agent for epoxy resin (a novolak-type phenol resin, an isophthalic acid dihydrazide, an adipic acid dihydrazide, etc.), etc. may be mentioned.

With respect to the addition amount of the curing agent, it is preferred to use from 0.5 to 2 equivalents, more preferred to use from 0.8 to 1.2 equivalents, to the amount of reactive groups in the thermosetting resin.

In the above-described method for producing a liquid composition of the present invention, a liquid composition is obtained by heat-treating a mixture comprising a resin powder, a binder component and a liquid medium, so that the viscosity change rate becomes to be from 5 to 200%. Thus, agglomeration of the resin powder in the liquid composition is prevented even at a low viscosity, whereby it is possible to obtain the liquid composition in which the resin powder is uniformly dispersed.

The cause for the improvement in dispersibility of the resin powder by the heat treatment is not necessarily clear, but is considered to be as follows. By the heat treatment, the functional group (i) of the resin powder and the reactive group of the binder component will react to some extent, and the binder component will be bonded to the resin powder, whereby the binder component becomes a physical hindrance, and the resin powder itself tends to hardly get close together. Further, the density of the reaction product of the resin powder and the binder component becomes lower than the density of the resin powder, whereby the sedimentation rate decreases. From these facts, the resin powder is considered to become excellent in dispersibility.

In the liquid composition obtained by the method for producing a liquid composition of the present invention, the resin powder is uniformly dispersed, whereby it is possible to form a film, etc. excellent in electrical properties. Further, in the formed film, etc., the functional group (i) of the resin powder and the reactive group of the binder component have reactivity, whereby adhesion between the resin powder and binder component will be excellent. Further, since the resin powder has a functional group (i), the formed film, etc. will be excellent in interlayer adhesion with another material (metal, etc.). In particular, when a substrate and a metal layer are laminated at a temperature near or exceeding the melting point of the polymer (X), an improvement in the adhesion between the layers can be expected, as compared with the case of using a conventional PTFE powder. Thus, even without a metal foil having a large surface roughness in order to obtain an anchor effect, with a metal foil having a small roughness, sufficient adhesion can be secured. Therefore, it is possible to reduce the conductor loss due to a large surface roughness of the metal foil.

For these reasons, the liquid composition obtainable by the method for producing a liquid composition of the present invention is preferably used in methods for producing the later-described film, fiber-reinforced film, prepreg and adhesive substrate to be suitably used for application to printed circuit boards. Further, the liquid composition obtainable by the method for producing a liquid composition of the present invention is preferably used to form an interlayer insulating film or solder resist of a printed circuit board.

Further, applications of the liquid composition are not limited to the above applications. For example, the liquid composition obtained by the method for producing a liquid composition of the present invention may be used in coated article applications as described in [0099] of WO2016/017801.

### [Method for Producing Film]

The method for producing a film of the present invention is a method comprising obtaining a liquid composition by the above-described method for producing a liquid composition of the present invention, and conducting film formation by using the obtained liquid composition, followed by drying and then by heating to obtain a film.

The film forming method of the liquid composition is not particularly limited, and may, for example, be a method of applying the liquid composition on a flat surface by a known wet coating method such as a spraying method, a roll coating method, a spin coating method, a bar coating method, etc.

After the film formation of the liquid composition, at least a portion the liquid medium is removed by drying. In the drying, it is not necessarily required to completely remove the liquid medium, and the drying may be conducted to such an extent that the coating film can stably maintain the film shape after the film formation. In the drying, it is preferred to remove at least 50 mass % out of the liquid medium contained in the liquid composition.

The drying method of the coating film after the film formation is not particularly limited, and may, for example, be a method of heating by an oven, a method of heating by a continuous drying furnace, etc.

The drying temperature may be within such a range that no bubble will form at the time of removing the liquid medium, and, for example, it is preferably from 50 to 250° C., more preferably from 70 to 220° C.

The drying time is preferably from 0.1 to 30 minutes, more preferably from 0.5 to 20 minutes.

The drying may be carried out in one step, or it may be carried out in two or more steps at different temperatures.

After the drying, the binder component is cured by heating. The drying and the subsequent heating may be performed continuously. The heating temperature after the drying is suitably set depending on the type of the binder component. For example, in a case where the binder component is a polyamic acid, it may be converted to a polyimide by heating at from 350 to 550° C. In a case where the binder component comprises an epoxy resin and a curing agent added after the heat treatment, it may be converted to a cured epoxy resin by heating at from 50 to 250° C.

The film obtainable by the method for producing a film of the present invention may be used to produce a metal laminate or a printed circuit board.

The thickness of the film is preferably from 1 to 3,000 μm. In the case of an application for a printed circuit board, the thickness of the film is more preferably from 3 to 2,000 μm, further preferably from 5 to 1,000 μm, particularly preferably from 6 to 500 μm.

The dielectric constant of the film is preferably from 2.0 to 3.5, particularly preferably from 2.0 to 3.0. When the dielectric constant is at most the upper limit value in the above range, it is useful in an application where a low dielectric constant is required, such as an application for a printed circuit board. When the dielectric constant is at least the lower limit value in the above range, the film will be excellent in both adhesion and electrical properties.

### [Method for Producing Fiber-Reinforced Film]

The method for producing a fiber-reinforced film of the present invention is a method comprising obtaining a liquid composition by the above-described method for producing a liquid composition of the present invention, and impregnating a reinforcing fiber material with the liquid composition, followed by drying and then by heating to obtain a fiber-reinforced film.

As reinforcing fibers for forming the reinforcing fiber material, glass fibers, aramid fibers, carbon fibers, etc. may be mentioned. As the reinforcing fibers, carbon fibers are preferred since they have a small specific gravity, high strength and high modulus. The reinforcing fibers may be ones having surface treatment applied. As the reinforcing fibers, one type may be used alone, or two or more types may be used in combination.

The form of the reinforcing fiber material is, from the viewpoint of the mechanical properties of the fiber reinforced film, preferably one processed into a sheet form. Specifically, for example, a cloth made by weaving reinforcing fiber bundles composed of a plurality of reinforcing fibers, a base material having a plurality of reinforcing fibers aligned unidirectionally, one having them stacked, etc. may be mentioned. Reinforcing fibers need not be continuous over the entire length in the longitudinal direction or over the entire width in the width direction of the reinforcing fiber sheet, and they may be divided in the middle.

After impregnating the reinforcing fiber material with the liquid composition, at least a portion of the liquid medium is removed by drying, followed by further heating. The drying and the heating after the impregnation may be conducted in the same manner as in the drying and the heating in the above-described method for producing a film.

The fiber-reinforced film obtainable by the method for producing a fiber-reinforced film of the present invention may be used to produce a metal laminate or a printed circuit board.

The thickness of the fiber-reinforced film is preferably from 1 to 3,000 μm. In the case of an application for a printed circuit board, the thickness of the fiber-reinforced film is more preferably from 3 to 2,000 μm, further preferably from 5 to 1,000 μm, particularly preferably from 6 to 500 μm.

The dielectric constant of the fiber-reinforced film is preferably from 2.0 to 3.5, particularly preferably from 2.0 to 3.0. When the dielectric constant is at most the upper limit value in the above range, it is useful in an application where a low dielectric constant is required such as an application for a printed circuit board. When the dielectric constant is at least the lower limit value in the above range, the fiber-reinforced film will be excellent in both adhesion and electrical properties.

### [Method for Producing Prepreg]

The method for producing a prepreg of the present invention is a method comprising obtaining a liquid composition by the above-described method for producing a liquid composition of the present invention, and impregnating a reinforcing fiber material with the liquid composition, followed by drying to obtain a prepreg. In the method for producing a prepreg of the present invention, the impregnation of the reinforcing fiber material with the liquid composition may be conducted in the same manner as in the method for producing a fiber-reinforced film.

Further, the drying after the impregnation may be conducted in the same manner as the drying in the method for producing a film. In the prepreg, the liquid medium may be left. In the prepreg, among the liquid medium contained in the liquid composition, it is preferred that at least 70 mass % is removed.

In the method for producing a prepreg, in a case where a thermosetting resin or raw material for a thermosetting resin is used as a binder component, such a curable resin may be made to be in a semi-cured state after the drying.

The prepreg obtainable by the method for producing a prepreg of the present invention may be used to produce a metal laminate or a printed circuit board. Further, a prepreg obtainable by the method of the present invention may be used in applications other than for electronic components such as printed circuit boards. For example, it is useful as a material for sheet pile which is required to be durable and light in weight in quay construction, a material for producing a member for various applications including aircrafts, automobiles, ships, wind turbines, sports goods, etc.

The dielectric constant of the prepreg is preferably from 2.0 to 3.5, particularly preferably from 2.0 to 3.0. When the dielectric constant is at most the upper limit value in the above range, it is useful in an application where a low dielectric constant is required such as an application for a printed circuit board. When the dielectric constant is at least the lower limit value in the above range, the prepreg will be excellent in both adhesion and electrical properties.

### [Method for Producing Adhesive Substrate]

The method for producing an adhesive substrate of the present invention is a method comprising obtaining a liquid composition by the above-described method for producing a liquid composition of the present invention, and applying the obtained liquid composition on at least one surface of a substrate, followed by drying and then by heating to obtain an adhesive substrate.

The method of applying the liquid composition to a substrate is not particularly limited, and, for example, the method mentioned in the method for producing a film may be mentioned.

The drying and the heating after application of the liquid composition may be conducted in the same manner as in the method for producing a film.

By the method for producing an adhesive substrate of the present invention, an adhesive substrate having a substrate and an adhesive layer comprising the resin powder and the binder component, formed on at least one surface of the substrate, is obtainable. The adhesive layer may be formed on only one surface in the thickness direction of the substrate, or it may be formed on both surfaces. From such a viewpoint that it will be easy to suppress warpage of the adhesive substrate and will be easy to obtain a metal laminate excellent in electrical reliability, it is preferred to form the adhesive layer on both sides of the substrate.

In the case of forming the adhesive layer on both surfaces of the substrate, it is preferred that after conducting application and drying of the liquid composition to one surface of a substrate, application and drying of the liquid composition to the other surface are conducted. The heating after the drying may be conducted after conducting application and drying of the liquid composition to both sides of the substrate, or after conducting from application to heating of the liquid composition to one side of the substrate, from application to heating of the liquid composition to the other surface may be conducted.

The thickness of the adhesive layer to be formed is preferably from 1 to 3,000 μm. In the case of an application for a printed circuit board, the thickness of the adhesive layer is more preferably from 3 to 2,000 μm, further preferably from 5 to 1,000 μm, particularly preferably from 6 to 500 μm.

In the case of forming adhesive layers on both sides of the substrate, the compositions and thicknesses of the respective adhesive layers may be made to be the same or may be made to be different. With a view to suppressing warpage of the adhesive substrate, it is preferred that the compositions and thicknesses of the respective adhesive layers are made to be the same.

The substrate is not particularly limited, and may, for example, be a heat-resistant resin film. A heat-resistant resin film is a film containing at least one heat-resistant resin. However, the heat-resistant resin film does not contain a fluorinated polymer. The heat-resistant resin film may be a monolayer film or may be a multilayer film.

The heat-resistant resin means a polymer compound having a melting point of at least 280° C. or a polymer compound with the maximum continuous use temperature as defined by JIS C4003: 2010 (IEC 60085: 2007) being at least 121° C. As the heat-resistant resin, for example, a polyimide (an aromatic polyimide, etc.), a polyarylate, a polysulfone, a polyaryl sulfone (a polyaryl ether sulfone, etc.), an aromatic polyamide, an aromatic polyether amide, a polyphenylene sulfide, a polyaryl ether ketone, a polyamideimide, a liquid crystal polyester, etc. may be mentioned.

As the heat-resistant resin film, a polyimide film is preferred. The polyimide film may contain additives, as the case requires, within a range not to impair the effects of the present invention. The heat-resistant resin film may be one having a surface treatment such as corona discharge treatment, plasma treatment, etc. applied to the surface having an adhesive layer laminated.

The adhesive substrate obtained by the method for producing an adhesive substrate of the present invention can be used to produce a metal laminate or a printed circuit board.

The dielectric constant of the adhesive substrate is preferably from 2.0 to 3.5, particularly preferably from 2.0 to 3.0. When the dielectric constant is at most the upper limit value in the above range, it is useful in an application where a low dielectric constant is required such as an application for a printed circuit board. When the dielectric constant is at least the lower limit value in the above range, the adhesive substrate will be excellent in both adhesion and electrical properties.

### [Method for Producing Metal Laminate]

The method for producing a metal laminate of the present invention is a method comprising obtaining a film, a fiber-reinforced film, a prepreg or an adhesive substrate by any of the above-described methods of the present invention, forming a substrate containing any of them, and forming a metal layer on one side or both sides of the substrate, to obtain a metal laminate. Thus, by using the film, the fiber-reinforced film, the prepreg or the adhesive substrate obtainable by the production method of the present invention as a substrate, it is possible to produce a metal laminate provided with the substrate and a metal layer formed on one side or both sides of the substrate.

The method of forming a metal layer on one side or both sides of the substrate may, for example, be a method of laminating a metal foil and the substrate, a method of vapor-depositing a metal on the surface of the substrate, etc. The method of laminating the metal foil and the substrate may, for example, be heat lamination, etc. The method for vapor-depositing a metal may be a vacuum vapor-deposition method, a sputtering method, an ion plating method, etc.

The metal to constitute the metal layer may be suitably selected depending on the application, and, for example, copper or a copper alloy, stainless steel or its alloy, etc. may be mentioned. As the metal foil, a copper foil such as a rolled copper foil or an electrolytic copper foil is preferred. On the surface of the metal foil, an anticorrosive layer (e.g. an oxide film such as a chromate) or a heat-resistant layer may be formed. Further, in order to improve the adhesion to the substrate, a coupling agent treatment, etc. may be applied on the surface of the metal foil.

The thickness of the metal layer is not particularly limited, and depending on the application of the metal laminate, a thickness whereby sufficient functions can be exhibited may be selected.

As the laminated structure of the metal laminate to be produced, in the case of using the film, fiber-reinforced film or prepreg obtained by the method of the present invention as a substrate, film/metal layer, metal layer/film/metal layer, fiber-reinforced film/metal layer, metal layer/fiber-reinforced film/metal layer, prepreg/metal layer, metal layer/prepreg/metal layer, etc. may be mentioned. In the case of using the adhesive substrate obtained by the method of the present invention as a substrate, the laminated structure of the metal laminate may be substrate/adhesive layer/metal layer, adhesive layer/substrate/metal layer, etc.

Further, one having the adhesive substrate and a layer of the polymer (X) laminated, may also be used as a substrate. As the layer of the polymer (X), it is possible to use, for example, a resin film having the polymer (X) formed into a film-form by a known molding method such as a casting method, an extrusion molding method, an inflation molding method, etc. The laminated structure of the metal laminate comprising a substrate having the adhesive substrate and a layer of the polymer (X) laminated, may be a laminated structure of e.g. metal layer/adhesive layer/substrate/layer of polymer (X)/substrate/adhesive layer/metal layer, metal layer/substrate/adhesive layer/layer of polymer (X)/adhesive layer/substrate/metal layer, metal layer/adhesive layer/substrate/adhesive layer/layer of polymer (X)/adhesive layer/substrate/adhesive layer/metal layer, etc.

The method for producing the metal laminate is not limited to the above-described method. For example, it may be a method comprising obtaining a liquid composition by the method for producing a liquid composition of the present invention, and applying the liquid composition to at least one side in the thickness direction of a metal foil, followed by drying and then by heating to form a film on the metal foil.

### [Method for Producing Printed Circuit Board]

The method for producing a printed circuit board of the present invention is a method comprising obtaining a metal laminate by the above-described method for producing a metal laminate of the present invention, and etching the metal layer of the metal laminate to form a pattern circuit to obtain a printed circuit board. Thus, by using the metal laminate obtainable by the above-described method for producing a metal laminate of the present invention, it is possible to produce a printed circuit board. As the method for producing a printed circuit board, for example, a method of forming a pattern circuit by etching the metal layer of the metal laminate obtained by the method for producing a metal laminate of the present invention, may be mentioned. For the etching of the metal layer, a known method may employed.

In the method for producing a printed circuit board of the present invention, after forming a pattern circuit by etching the metal layer, an interlayer insulating film may be formed on the pattern circuit, and a pattern circuit may further be formed on the interlayer insulating film. The interlayer insulating film may be formed, for example, by a liquid composition obtainable by the method of the present invention.

Specifically, for example, the following method may be mentioned. After forming a pattern circuit by etching the metal layer of the metal laminate having any optional multilayer structure, a liquid composition obtained by the method for producing a liquid composition of the present invention is applied on the pattern circuit, followed by drying and then by heating to form an interlayer insulating film. Then, a metal layer is formed by vapor deposition, etc. on the interlayer insulating film, followed by etching to further form a pattern circuit.

In the production of a printed circuit board, a solder resist may be laminated on the pattern circuit. The solder resist may be formed, for example, by a liquid composition obtainable by the production method of the present invention. Specifically, the solder resist may be formed by applying the liquid composition obtained by the method for producing a liquid composition of the present invention on the pattern circuit, followed by drying and then by heating.

Further, in the production of a printed circuit board, a coverlay film may be laminated. A coverlay film is typically composed of a substrate film and an adhesive layer formed on its surface, and the surface on the adhesive layer side is bonded to the printed circuit board. As the base film for the coverlay film, for example, a film obtained by the production method of the present invention may be used.

Further, on a pattern circuit formed by etching a metal layer of a metal laminate, an interlayer insulating film (adhesive layer) using a film obtained by the production method of the present invention, may be formed, and a polyimide film as a coverlay film may be laminated.

The above-described printed circuit board obtainable by the production method of the present invention is useful as a substrate for electronics such as radars, network routers, backplanes, wireless infrastructures required to have high frequency characteristics, as a substrate for various sensors for automobiles, or as a substrate for engine management sensors, and it is particularly suitable for applications in which reduction of the transmission loss in the millimeter wave band is intended.

### EXAMPLES

In the following, the present invention will be described in detail with reference to Examples. However, the present invention is not limited by the following description.

### [Measuring Methods]

Various measuring methods with respect to the polymer (X) and the resin powder will be shown below.

### (1) Copolymer Composition

In the copolymer composition of the polymer (X), the proportion of units based on NAH (mol %), was obtained by the following infrared absorption spectrum analysis. The proportion of units other than units based on NAH was obtained by the melt NMR analysis and fluorine content analysis.

<Proportion of Units Based on NAH (mol %)>

A film having a thickness of 200 μm was obtained by press-molding the polymer (X) and then analyzed by infrared spectroscopy to obtain an infrared absorption spectrum. In the infrared absorption spectrum, the absorption peak in units based on NAH in the polymer (X) appears at 1,778 cm⁻¹. The absorbance of the absorption peak was measured, and by using the molar extinction coefficient of NAH being 20,810 mol⁻¹19 |·cm⁻¹, the proportion of units based on NAH in the polymer (X) was obtained.

### (2) Melting Point (° C.)

Using a differential scanning calorimeter (DSC apparatus) manufactured by Seiko Instruments Inc., the melting peak at the time of heating the polymer (X) at a rate of 10° C./min. was recorded, and the temperature (° C.) corresponding to the maximum value was taken as the melting point (Tm).

(3) MFR (g/10 min.)

Using a melt indexer manufactured by Technol Seven Co., Ltd., the mass (g) of the polymer (X) flowing out in 10 minutes (unit time) from a nozzle having a diameter of 2 mm and a length of 8 mm at 372° C. under a load of 49N, was measured and taken as MFR.

### (4) Dielectric Constant

In a test environment where by a transformer bridge method in accordance with ASTM D150, the temperature was maintained in a range of 23° C.±2° C. and the relative humidity was maintained in a range of RH 50%±5%, a value obtained at 1 MHz by the dielectric breakdown testing device (YSY-243-100RHO (manufactured Yamayoshikenki Co.)) was taken as the dielectric constant.

### (5) Average Particle Size of Resin Powder

A 2.000 mesh sieve (mesh opening: 2.400 mm), a 1.410 mesh sieve (mesh opening: 1.705 mm), a 1.000 mesh sieve (mesh opening: 1.205 mm), a 0. 710 mesh sieve (mesh opening: 0.855 mm), a 0.500 mesh sieve (mesh opening: 0.605 mm), a 0.250 mesh sieve (mesh opening: 0.375 mm), a 0.149 mesh sieve (mesh opening: 0.100 mm) and a saucer were stacked in this order from the top. A sample (polymer (X)) was put thereon and sieved by a shaker for 30 minutes. Thereafter, the mass of the sample remaining on each sieve was measured, and the cumulative total of the mass passed through each sieve opening value was represented on a graph, whereupon the particle size at the time when the cumulative total of the mass passed was 50% was taken as the average particle size of the sample.

### (6) Average Particle Size and D90 of Resin Powder

Using a laser diffraction and diffusion particle size distribution measuring apparatus (LA-920 instrument) manufactured by Horiba Ltd., a resin powder was dispersed in water and the particle size distribution was measured, whereupon the average particle size (μm) and D90 (μm) were calculated.

### (7) Loosely Packed Bulk Density and Densely Packed Bulk Density

The loosely packed bulk density and densely packed bulk density of a resin powder were measured by using the method described in [0117] and [0118] of WO2016/017801.

### Production Example 1

Using NAH (himic anhydride, manufactured by Hitachi Chemical Co., Ltd.) as a monomer to form units (1) and PPVE (CF₂═CFO(CF₂)₃F, manufactured by Asahi Glass Company, Limited), the polymer (X-1) was produced in the procedure as described in of WO2016/017801.

The copolymer composition of the polymer (X-1) was units based on NAH/TFE units/PPVE units=0.1/97.9/2.0 (mol %). The melting point of the polymer (X-1) was 300° C., the dielectric constant was 2.1, MFR was 17.6 g/10 min., and the average particle size was 1,554 μm.

Then, using a jet mill (a single track jet mill FS-4 Model manufactured by Seishin Enterprise Co., Ltd.), the polymer (X-1) was pulverized under conditions of a pulverization pressure of 0.5 MPa and a treating speed of 1 kg/hr to obtain a resin powder. The average particle size of the resin powder was 2.58 μm, and D90 was 7.1 μm. The loosely packed bulk density of the resin powder was 0.278 g/mL, and the densely packed bulk density was 0.328 g/mL.

### Example 1

To the resin powder produced in Production Example 1, a surfactant (trade name “Newcol 1308”, manufactured by Nippon Nyukazai Co., Ltd.) was added in an amount of 3 mass % to the resin powder, and further, methyl ethyl ketone (hereinafter referred to as “MEK”) was added to bring the solid content concentration to 40 mass %, followed by stirring for 1 hour under a condition of 300 rpm and then by stirring for 15 minutes at 1,500 rpm. Then, by an ultrasonic homogenizer, ultrasonic treatment was conducted for 5 minutes, whereupon a resin powder dispersion liquid was obtained. Then, to an epoxy resin main agent (manufactured by DIC Corporation, trade name: EPICLON HP-7200H-75M, a liquid medium: MEK, solid content concentration: 75 mass %), the resin powder dispersion liquid and MEK were added, so as to be solid content in the main agent:resin powder:MEK=26:25:40 (mass ratio), followed by stirring for one hour under a condition of 1,000 rpm by a stirrer to obtain a mixture.

The above mixture was subjected to heat treatment at 50° C. for 30 minutes and then cooled to room temperature. The viscosity of the mixture before the heat treatment was 4,500 mPasec, the viscosity of the mixture after the heat treatment was 5,000 mPasec, and the viscosity change rate as between before and after the heat treatment was 111%.

To the mixture after the heat treatment, a curing agent (manufactured by DIC Corporation, trade name: Phenolite TD-2090-60M, solvent: MEK, solid content: 60 mass %) for an epoxy resin was added so as to be solid content in the main agent:solid content in the curing agent=26:9 (mass ratio) and stirred for 20 minutes under a condition of 1,000 rpm by a stirrer to obtain a liquid composition.

### Example 2

To the resin powder produced in Production Example 1, a surfactant (trade name “FTERGENT 710-FL”, manufactured by NEOS COMPANY LIMITED) was added in an amount of 10 mass % to the resin powder, and further MEK was added to bring the powder concentration to be 30 mass %, followed by stirring for one hour under a condition of 200 rpm by a 3 L ball mill mixer, to obtain a resin powder dispersion liquid. Then, to the same epoxy resin main agent as in Example 1, the resin powder dispersion liquid and MEK were added so as to be solid content in the main agent:resin powder:MEK=37.5:15:46 (mass ratio), followed by stirring for 15 minutes under a condition of 200 rpm by a stirrer to obtain a mixture.

The above mixture was subjected to heat treatment at 50° C. for 30 minutes and then cooled to room temperature. The viscosity of the mixture before the heat treatment was 480 mPasec, the viscosity of the mixture after the heat treatment was 520 mPasec, and the viscosity change rate as between before and after the heat treatment was 108%.

To the mixture after the heat treatment, the same curing agent for an epoxy resin as in Example 1 was added so as to be solid content in the main agent:solid content in the curing agent=26:9 (mass ratio), followed by stirring for 20 minutes under a condition of 200 rpm by a stirrer, to obtain a liquid composition.

### Example 3

To the resin powder produced in Production Example 1, the same surfactant as in Example 2 was added in an amount of 13 mass % to the resin powder, and further, cyclohexanone was added to bring the powder concentration to be 30 mass %, followed by stirring for one hour under a condition of 200 rpm by a 3 L ball mill mixing machine, to obtain a resin powder dispersion liquid. Then, to the same epoxy resin main agent as in Example 1, the resin powder dispersion liquid and MEK were added so as to be solid content in the main agent:resin powder:MEK=37.5:15:46 (mass ratio), followed by stirring for 15 minutes under a condition of 200 rpm by a stirrer to obtain a mixture.

The above mixture was subjected to heat treatment at 50° C. for 30 minutes and then cooled to room temperature. The viscosity of the mixture before the heat treatment was 180 mPasec, the viscosity of the mixture after the heat treatment was 270 mPasec, and the viscosity change rate as between before and after the heat treatment was 150%.

To the mixture after heat treatment, the same curing agent for an epoxy resin as in Example 1 was added so as to be solid content in the main agent:solid content in the curing agent=26:9 (mass ratio), followed by stirring for 20 minutes under a condition of 200 rpm by a stirrer, to obtain a liquid composition.

### Comparative Example 1

A liquid composition was obtained in the same manner as in Example 1 except that no heat treatment was conducted.

### [Evaluation Methods]

The liquid composition obtained in each Example was evaluated for the following (a) to (d).

(a) The appearance of the liquid composition immediately after the production was visually observed, whereby the presence or absence of agglomeration of the resin powder was judged. A case where no agglomeration of the resin powder was observed, was judged to be ◯ (good), and a case where agglomeration of the resin powder was observed, was judged to be × (bad).

(b) After the judgement of the above (a), the liquid composition was filtered through a 100 mesh filter, whereupon whether or not agglomerates were present on the filter was visually determined. A case where no agglomerates were observed was judged to be ◯ (good), and a case where agglomerates were observed was judged to be × (bad).

(c) A portion of the liquid composition after the filtration of the above (b) was taken out and left to stand still for 3 hours, whereupon the presence or absence of solid-liquid separation due to sedimentation of the resin powder was visually determined. A case where no solid-liquid separation was observed was judged to be ◯ (good), and a case where solid-liquid separation was observed was judged to be × (bad).

(d) On an electrolytic copper foil with a thickness of 12 μm (manufactured by Fukuda Metal Foil & Powder Co., Ltd., CF-T4X-SVR-12, surface roughness (Rz): 1.2 μm), the liquid composition after the filtration of the above (b) was applied and dried in an oven to form a film having a thickness of 35 μm, thereby to obtain a one-side copper clad laminate of copper foil/film. In the drying, heating was sequentially conducted for 10 minutes at 60° C., for 10 minutes at 100° C., and for 5 minutes at 170° C., in this order. The film in the above one-side copper clad laminate was visually observed. A case where no agglomerates were observed in the film, and no color unevenness caused by the plaque of the resin powder was observed, was judged to be ◯ (good), and a case where agglomerates were observed, and color unevenness caused by the plaque of the resin powder was observed, was judged to be × (bad).

The evaluation results are shown in Table 1.

TABLE 1

| | | | | Comparative |
|---|---|---|---|---|
| | Example 1 | Example 2 | Example 3 | Example 1 |
| Evaluation (a) | ∘ | ∘ | ∘ | x |
| Evaluation (b) | ∘ | ∘ | ∘ | x |
| Evaluation (c) | ∘ | ∘ | ∘ | x |
| Evaluation (d) | ∘ | ∘ | ∘ | x |

As shown in Table 1, in Example 1, in the liquid composition immediately after the production, no agglomerates of the resin powder were observed on appearance. Further, also on the filter after the filtration, no agglomerates were observed, and in the liquid composition left to stand after the filtration, no solid-liquid separation due to sedimentation of the resin powder was observed. Furthermore, in the film of the one-side copper clad laminate, no agglomerates were observed, and the film had a uniform color and had the resin powder uniformly distributed.

On the other hand, in Comparative Example 1, in the liquid composition left to stand after the filtration, solid-liquid separation due to sedimentation of the resin powder was observed. Further, agglomerates were observed in the film of the one-side copper clad laminate, and in the film, color unevenness due to poor dispersion of the resin powder was observed.

### INDUSTRIAL APPLICABILITY

A complex, a molded product, a ceramic molded product, a metal laminate, a printed circuit board, a prepreg, etc. formed by using the resin powder obtainable by the present invention, can be used as antenna parts, printed circuit boards, aircraft parts, automotive parts, sports equipment and coated articles such as food industrial products, saws, sliding bearings, etc.

This application is a continuation of PCT Application No. PCT/JP2017/023092, filed on Jun. 22, 2017, which is based upon and claims the benefit of priority from Japanese Patent Application No. 2016-124649 filed on Jun. 23, 2016. The contents of those applications are incorporated herein by reference in their entireties.

What is claimed is:

1. A method for producing a liquid composition, comprising heat-treating a mixture comprising a resin powder having an average particle size of from 0.02 to 200 μm made of a powder material containing the following polymer (X), a binder component having a reactive group reactive with the functional group of the resin powder, and a liquid medium capable of dissolving the binder component, to obtain a liquid composition, of which the viscosity change rate to the viscosity before heating is from 5 to 200%,
Polymer (X): a fluorinated polymer having units based on tetrafluoroethylene, and having at least one functional group selected from the group consisting of a carbonyl group-containing group, a hydroxy group, an epoxy group and an isocyanate group.

2. The method for producing a liquid composition according to claim 1, wherein the polymer (X) is a copolymer containing units having the functional group and units based on tetrafluoroethylene.

3. The method for producing a liquid composition according to claim 1, wherein the melting point of the polymer (X) is from 260 to 380° C.

4. The method for producing a liquid composition according to claim 1, wherein the polymer (X) is a melt-moldable fluorinated copolymer having a melting point of from 260 to 320° C.

5. The method for producing a liquid composition according to claim 1, wherein the polymer (X) is a copolymer containing units having the functional group, units based on tetrafluoroethylene and units based on a perfluoro(alkyl vinyl ether), in which the proportions of the respective units to the total of all units are as follows:
Units having the functional group: from 0.01 to 3 mol %,
Units based on tetrafluoroethylene: from 90 to 99.89 mol %,
Units based on a perfluoro(alkyl vinyl ether): from 0.1 to 9.99 mol %.

6. The method for producing a liquid composition according to claim 1, wherein the functional group is a carbonyl group-containing group, and said carbonyl group-containing group is a group having a carbonyl group between carbon atoms of a hydrocarbon group, a carbonate group, a carboxy group, a haloformyl group, an alkoxycarbonyl group or an acid anhydride residual group.

7. The method for producing a liquid composition according to claim 1, wherein the average particle size of the resin powder is from 0.02 to 10 μm.

8. The method for producing a liquid composition according to claim 1, wherein the reactive group is a carbonyl group-containing group, a hydroxy group, an amino group or an epoxy group.

9. The method for producing a liquid composition according to claim 1, wherein said mixture further contains a filler.

10. A method for producing a film, comprising obtaining a liquid composition by the method for producing a liquid composition as defined in claim 1, and conducting film formation by using the obtained liquid composition, followed by drying and then by heating to obtain a film.

11. A method for producing a fiber-reinforced film, comprising obtaining a liquid composition by the method for producing a liquid composition as defined in claim 1, and impregnating a reinforcing fiber base material with the obtained liquid composition, followed by drying and then by heating to obtain a fiber-reinforced film.

12. A method for producing a prepreg, comprising obtaining a liquid composition by the method for producing a liquid composition as defined in claim 1, and impregnating a reinforcing fiber base material with the obtained liquid composition, followed by drying to obtain a prepreg.

13. A method for producing an adhesive substrate, comprising obtaining a liquid composition by the method for producing a liquid composition as defined in claim 1, and applying the obtained liquid composition on at least one surface of a substrate, followed by drying and then by heating to obtain an adhesive substrate.

14. A method for producing a metal laminate, comprising obtaining a film by the method for producing a film as defined in claim 10, forming a substrate containing the film, and forming a metal layer on one or both surfaces of said substrate to obtain a metal laminate.

15. A method for producing a metal laminate, comprising obtaining a fiber-reinforced film by the method for producing a fiber-reinforced film as defined in claim 11, forming a substrate containing the fiber-reinforced film, and forming a metal layer on one or both surfaces of said substrate to obtain a metal laminate.

16. A method for producing a metal laminate, comprising obtaining a prepreg by the method for producing a prepreg as defined in claim 12, forming a substrate containing the prepreg, and forming a metal layer on one or both surfaces of said substrate to obtain a metal laminate.

17. A method for producing a metal laminate, comprising obtaining an adhesive substrate by the method for producing an adhesive substrate as defined in claim 13, forming a substrate containing the adhesive substrate, and forming a metal layer on one or both surfaces of said substrate to obtain a metal laminate.

18. A method for producing a printed circuit board, comprising obtaining a metal laminate by the method for producing a metal laminate as defined in claim 14, and etching the metal layer to form a pattern circuit to obtain a printed circuit board.

19. A method for producing a printed circuit board, comprising obtaining a metal laminate by the method for producing a metal laminate as defined in claim 15, and etching the metal layer to form a pattern circuit to obtain a printed circuit board.

20. A method for producing a printed circuit board, comprising obtaining a metal laminate by the method for producing a metal laminate as defined in claim 16, and etching the metal layer to form a pattern circuit to obtain a printed circuit board.

21. A method for producing a printed circuit board, comprising obtaining a metal laminate by the method for producing a metal laminate as defined in claim 17, and etching the metal layer to form a pattern circuit to obtain a printed circuit board.
